(19) United States
(12) Patent Application Publication
(10) Pub. No.: US 2011/0232877 A1
(43) Pub. Date: Sep. 29, 2011

(54) COMPACT VAPOR CHAMBER AND HEAT-DISSIPATING MODULE HAVING THE SAME

(75) Inventors: George Anthony Meyer, IV, San Jose, CA (US); Chien-Hung Sun, Zhongli City (TW); Chieh-Ping Chen, Zhongli City (TW)

(73) Assignee: Celsia Technologies Taiwan, Inc.

(21) Appl. No.: 12/729,279

(22) Filed: Mar. 23, 2010

(51) Int. Cl. F28D 15/04; H01L 23/427

(52) U.S. Cl. 165/104.26; 165/104.33

(57) ABSTRACT

A compact vapor chamber configured to thermally conduct heat of an electronic heat-generating element includes a flat sealed casing; a wick structure arranged on inner walls of the flat sealed casing; a working fluid filled inside the flat sealed casing; and an evaporating section formed on a portion of the vapor chamber. An outer surface of the flat sealed casing on the evaporating section has a recess for covering the electronic heat-generating element. The recess is brought into thermal contact with the electronic heat-generating element. With this arrangement, when the compact vapor chamber is brought into thermal contact the electronic heat-generating element for heat dissipation, the distance of the electronic heat-generating element protruding from the compact vapor chamber is reduced, thereby facilitating the compact design of an electronic product. Further, the present invention provides a heat-dissipating module having such a compact vapor chamber.

### BACKGROUND OF THE INVENTION

1. Field of the Invention

The present invention relates to a heat-dissipating device, and in particular to a compact vapor chamber and a heat-dissipating module having such a compact vapor chamber.

2. Description of Prior Art

With the advancement of science and technology, the power and efficiency of electronic elements are gradually increased, so that each of the electronic elements generates a lot of heat during its operation. If the heat is not dissipated to the outside and accumulated in the electronic element, the temperature of the electronic element will rise to affect its performance and even suffer damage. Thus, manufacturers in this art continuously aim to develop various heat-dissipating devices to solve the above problem. A vapor chamber is one of the popular heat-dissipating devices.

The vapor chamber includes a flat sealed casing, a wick structure arranged inside the flat sealed casing, and a working fluid filled in the flat sealed casing. The flat sealed casing has a heat-absorbing surface and a heat-releasing surface opposite to the heat-absorbing surface. The heat-absorbing surface is brought into thermal contact with an electronic heat-generating element. By means of vapor-liquid phase change of the working liquid in the vapor chamber, the heat generated by the electronic heat-generating element can be conducted from the heat-absorbing surface to the heat-releasing surface.

Recently, since electronic products tend to be made compact, the thickness of the vapor chamber has to be reduced accordingly. Even several millimeters of reduction in the thickness is a breakthrough for the compact design of electronic products. As for a notebook computer, a central processing unit (CPU) connected on a mother board of the notebook computer is the most important operating element. Thus, the CPU is an electronic element generating the largest amount of heat. However, the conventional vapor chamber is of a planar structure, whose heat-absorbing surface is brought into thermal contact with the top surface of the CPU for heat dissipation. Thus, it is apparent that a gap inevitably exists between the vapor chamber and the mother board, and the gap is substantially identical to the thickness of the CPU. If the vapor chamber is thermally conducting the heat of the CPU in such a manner that the distance of CPU protruding from the vapor chamber is also reduced, the total thickness of the electronic product can be reduced, which facilitates the compact design thereof.

In view of the above problems, the present Inventor proposes a novel and reasonable structure based on his expert experience and deliberate researches.

### SUMMARY OF THE INVENTION

The present invention is to provide a compact vapor chamber, which is capable of reducing the distance of an electronic heat-generating element protruding form the vapor chamber while the vapor chamber is brought into thermal contact with the electronic heat-generating element for heat dissipation, thereby facilitating the compact design of an electronic product.

The present invention is to provide a heat-dissipating module having a compact vapor chamber, which is capable of rapidly dissipating the heat generated by an electronic heat-generating element to the outside with a reduced thickness, thereby facilitating the compact design of an electronic product.

The present invention provides a compact vapor chamber, configured to thermally conduct heat of an electronic heat-generating element and including: a flat sealed casing; a wick structure arranged on inner walls of the flat sealed casing; a working fluid filled inside the flat sealed casing; and an evaporating section formed on a portion of the vapor chamber, an outer surface of the flat sealed casing on the evaporating section having a recess for covering the electronic heat-generating element, the recess being brought into thermal contact with a top surface of the electronic heat-generating element.

The present invention is to provide a heat-dissipating module having a compact vapor chamber, configured to dissipate heat of an electronic heat-generating element and including: a compact vapor chamber comprising a flat sealed casing; a wick structure arranged on inner walls of the flat sealed casing; a working fluid filled inside the flat sealed casing; and an evaporating section formed on a portion of the vapor chamber, an outer surface of the flat sealed casing on the evaporating section having a recess for covering the electronic heat-generating element, the recess being brought into thermal contact with a top surface of the electronic heat-generating element; and a heat-dissipating fin assembly connected to the other portion of the flat sealed casing away from the evaporating section.

In comparison with prior art, the present invention has advantageous features as follows.

According to the compact vapor chamber of the present invention, a recess is formed on the evaporating section and located to correspond to the electronic heat-generating element, and the recess is configured to receive a portion of the electronic heat-generating element therein and thermally contact the top surface of the electronic heat-generating element. Thus, the problem that a gap inevitably exits between the conventional vapor chamber and the electronic heat-generating element can be avoided. The compact vapor chamber of the present invention has a recess for receiving a portion of the electronic heat-generating element, so that the distance of the electronic heat-generating element protruding from the vapor chamber can be reduced, which facilitates the compact design of an electronic product.

According to the above, since the compact vapor chamber of the present invention has a recess located to correspond to the electronic heat-generating element, the recess has an additional effect of locating the vapor chamber onto the electronic heat-generating element in a correct position.

Further, according to another embodiment, the recess is brought into thermal contact with a top surface and peripheral surfaces of the electronic heat-generating element, thereby increasing the heat-conducting area to rapidly conduct the heat of the electronic heat-generating element to other place.

According to the heat-dissipating module of the present invention, a heat-dissipating fin assembly is connected to the other portion of the vapor chamber away from the evaporating section (i.e., a condensing section), so that the thickness of the vapor chamber can be thus reduced to facilitate the compact design of the vapor chamber. Further, the combination of the heat-dissipating fin assembly and the condensing section generates a stronger effect for heat dissipation than that achieved by the vapor chamber only.

### BRIEF DESCRIPTION OF THE DRAWINGS

FIG. 1 is a perspective view showing a compact vapor chamber of the present invention;

FIG. 2 is a side cross-sectional view showing the compact vapor chamber of the present invention, on which a recess is formed;

FIG. 3 is a schematic view showing the operating state of a heat-dissipating module constituted of the compact vapor chamber of the present invention and a heat-dissipating fin assembly;

FIG. 4 is another side cross-sectional view showing that the present invention is used for the heat dissipation of an electronic heat-generating element, wherein the recess is brought into thermal contact with the top surface of the electronic heat-generating element; and

FIG. 5 is a side cross-sectional view showing that another embodiment of the present invention is used for the heat dissipation of an electronic heat-generating element, wherein the recess is brought into thermal contact with the top surface and peripheral surfaces of the electronic heat-generating element.

### DETAILED DESCRIPTION OF THE INVENTION

The characteristics and technical contents of the present invention will be described with reference to the accompanying drawings. However, the drawings are illustrative only, but not used to limit the present invention.

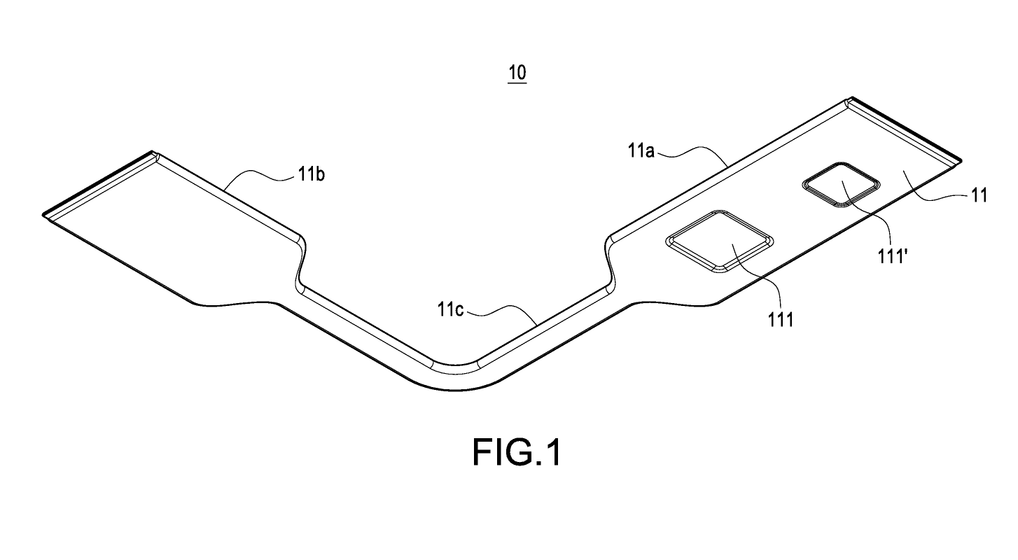

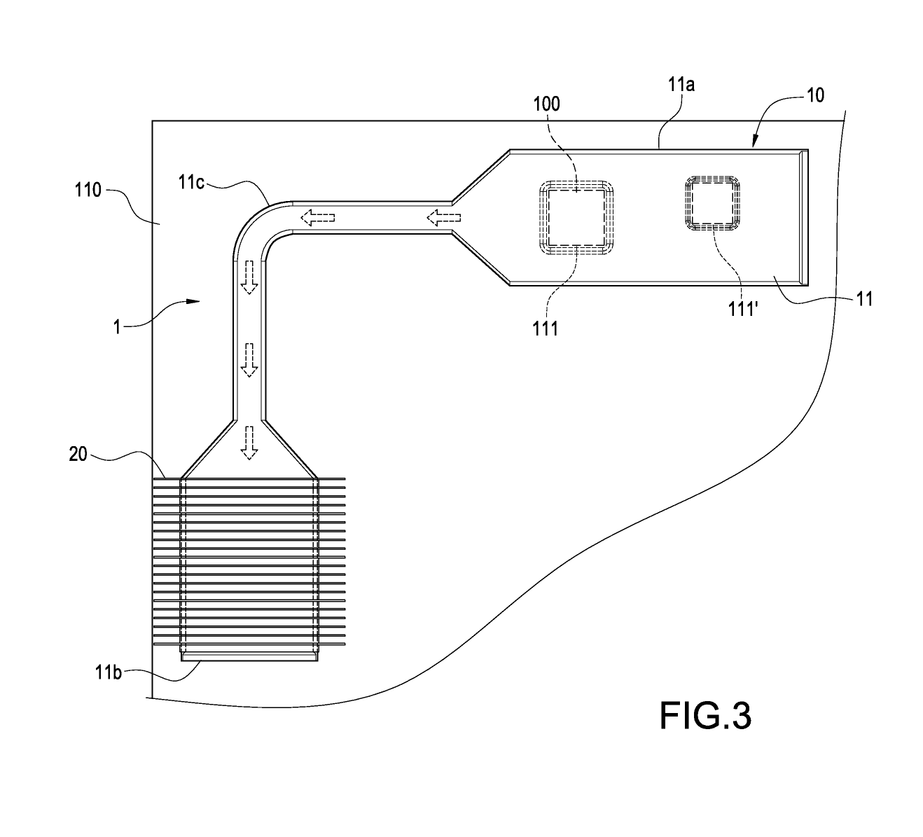

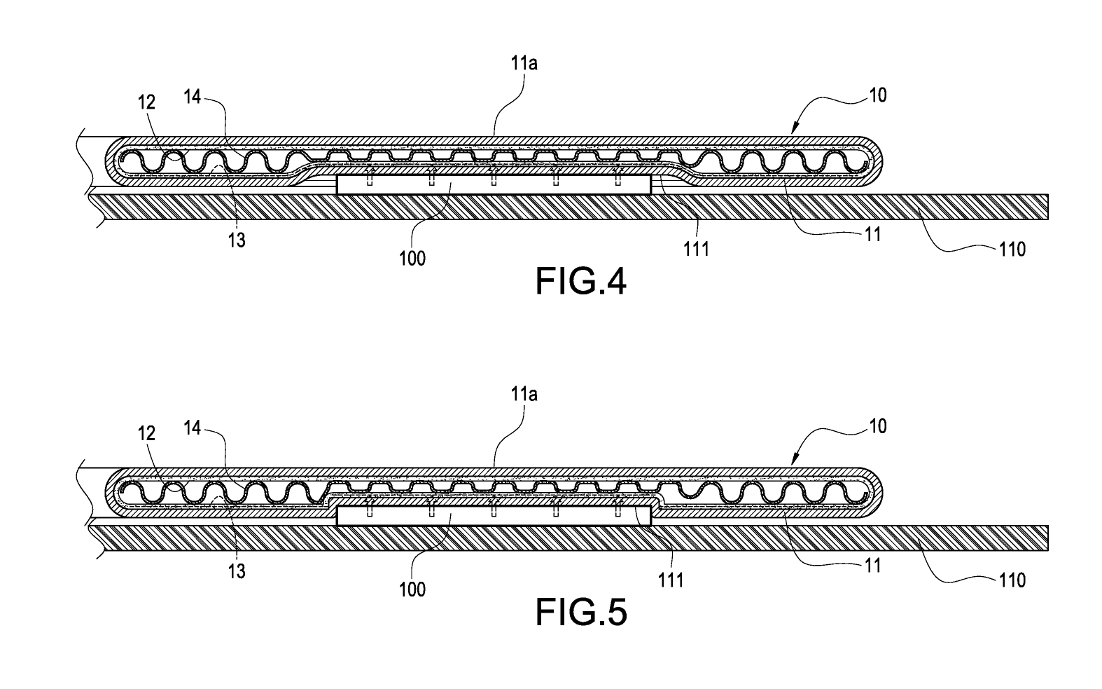

Please refer to FIGS. 1 to 4. The present invention provides a compact vapor chamber 10 (referred to as “vapor chamber 10” hereinafter) and a heat-dissipating module 1 having such a compact vapor chamber 10. The vapor chamber 10 is used to thermally conduct heat of an electronic heat-generating element 100, while the heat-dissipating module 1 is used to dissipate the heat of the electronic heat-generating element 100. The electronic heat-generating element 100 is electrically connected to a circuit board 110 (as shown in FIGS. 3 and 4).

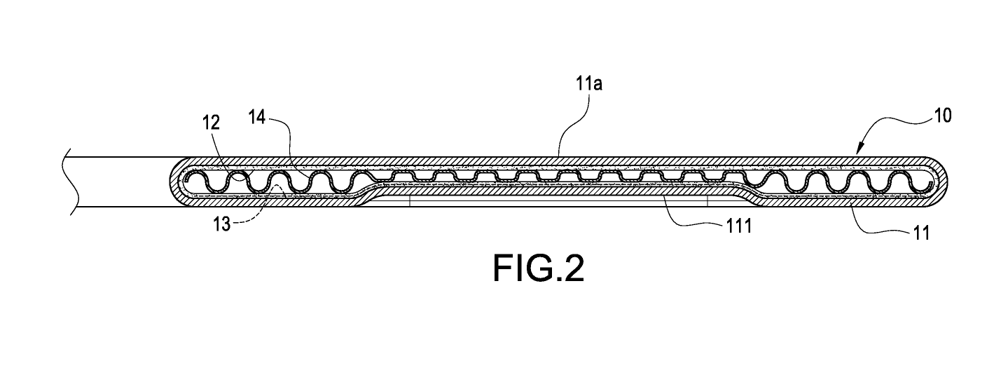

As shown in FIG. 2, the vapor chamber 10 is constituted of a flat sealed casing 11, a wick structure 12 arranged on inner walls of the flat sealed casing 11, a working fluid 13 (indicated by dotted lines) filled inside the flat sealed casing 11, and a supporting structure 14 for supporting the wick structure 12 to abut the flat sealed casing 11.

The flat sealed casing 11 is made of a metallic material having good heat conductivity. The vapor chamber 10 has an evaporating section 11a for abutting the electronic heat-generating element 100, a condensing section 11b located away from the evaporating section 11a, and an adiabatic section 11c extending between the evaporating section 11a and the condensing section 11b.

An outer surface of the flat sealed casing 11 on the evaporating section 11a is formed with a recess 111 for covering the electronic heat-generating element 100. The recess 111 is brought into thermal contact with the top surface of the electronic heat-generating element 100. It should be understood that the number of the recess 111 is not limited to one, and two or more recesses 111 and 111′ of different sizes shown in FIG. 1 may be used as long as the recesses 111 and 111′ are located to thermally contact the electronic heat-generating elements respectively.

The internal structure of the condensing section 11b is identical to that of the evaporating section 11a. However, since the condensing section 11b is located away from the evaporating section 11a without abutting the electronic heat-generating element 100, the condensing section 11a is not formed with the recess 111.

The adiabatic section 11c extends between the evaporating section 11a and the condensing section 11b for conducting the heat absorbed by a heat-absorbing surface of the evaporating section 11a into the condensing section 11b in an adiabatic manner. The adiabatic section 11c shown in FIG. 1 has a bending point, so that the evaporating section 11a is not collinear with the condensing section 11b. Of course, the shape of the adiabatic section 11c can be changed according to practice demands. For example, the adiabatic section 11c may be formed as a straight line or have at least one bending points.

The wick structure 12 is made by sintered powders or metallic meshes. The interior of the wick structure has a large amount of tiny holes for generating a capillary action. The wick structure 12 is arranged on inner walls of the flat sealed casing 11. The working fluid 13 is filled inside the flat sealed casing 11. As shown in FIG. 4, when the recess 111 is adhered to the top surface of the electronic heat-generating element 100, a portion of the working fluid 13 adjacent to the recess 111 absorbs the heat of the electronic heat-generating element 100 to change into its vapor phase, the vapor-phase working fluid 13 flows through the adiabatic section 11c toward the condensing section 11b. In the condensing section 11b, the heat of the working fluid 13 is released to return to its liquid phase. Then, the liquid-phase working fluid 13 flows back to the evaporating section 11a through the adiabatic section 11c. By means of the vapor-liquid phase change of the working fluid 13 circulating in the flat sealed casing 11, the heat generated by the electronic heat-generating element 100 can be rapidly conducted to other place by the vapor chamber 10.

As shown in FIG. 2, the supporting structure 14 is received in the flat sealed casing 11 to support the capillary structure 12, so that the wick structure 12 can surely abut the inner walls of the flat sealed casing 11. On the other hand, the supporting structure 14 provides a supporting force large enough to protect the flat sealed casing 11 from suffering deformation due to an external force. Since a portion of the flat sealed casing 11 is formed with the recess 111, the thickness of the portion of the supporting structure 14 corresponding to the recess 111 is smaller than that of the rest of the supporting structure 14.

Please refer to FIG. 3, which shows the heat-dissipating module 1 having the compact vapor chamber 10. The heat-dissipating module 1 includes the compact vapor chamber 10 and a heat-dissipating fin assembly 20. The heat-dissipating fin assembly 20 is connected to the condensing section 11b and has a plurality of heat-dissipating fins. Thus, the heat-dissipating fin assembly 20 can rapidly dissipate the heat of the condensing section 11b to the outside, thereby dissipating the heat of the electronic heat-generating element 100. In this way, the temperature the electronic heat-generating element 100 can be kept in a range for normal operation. Since the structure and function of the heat-dissipating fin assembly 20 are well known, the description relating thereto is omitted for clarity.

Please refer to FIG. 5, which shows another embodiment of the present invention. The difference between the present embodiment and the previous embodiment lies in that: the recess 111 is tightly fitted with the electronic heat-generating element 100, so that the recess 111 can be brought into thermal contact with the top surface and peripheral surfaces of the electronic heat-generating element 100, thereby increasing the heat-conducting area to rapidly conduct the heat of the electronic heat-generating element to other place.

In comparison with prior art, the present invention has advantageous features as follows.

According to the compact vapor chamber 10 of the present invention, since a recess 111 is formed on the evaporating section 11a and located to correspond to the electronic heat-generating element 100, and the recess 111 is configured to receive a portion of the electronic heat-generating element 100 therein and thermally contact the surface of the electronic heat-generating element 100, the problem that a gap inevitably exits between the conventional vapor chamber and the electronic heat-generating element can be avoided. The vapor chamber 10 of the present invention has a recess 111 for receiving a portion of the electronic heat-generating element 100, so that the distance of the electronic heat-generating element 100 protruding from the vapor chamber 10 can be reduced, which facilitates the compact design of an electronic product.

According to the above, the compact vapor chamber 10 of the present invention has a recess 111 located to correspond to the electronic heat-generating element 100, so that the recess 111 has an additional effect of locating the vapor chamber 10 onto the electronic heat-generating element 100 in a correct position.

Further, according to another embodiment, the recess 111 is brought into thermal contact with a top surface and peripheral sides of the electronic heat-generating element 100, thereby increasing the heat-conducting area to rapidly conduct the heat of the electronic heat-generating element 100 to other place.

According to the heat-dissipating module 1 of the present invention, a heat-dissipating fin assembly 20 is connected to the other portion of the vapor chamber 10 away from the evaporating section 11a (i.e., a condensing section 11b), the thickness of the vapor chamber 10 can be thus reduced to facilitate the compact design thereof. Further, the combination of the heat-dissipating fin assembly 20 and the condensing section 11b generates a stronger effect for heat dissipation than that achieved by the vapor chamber 10 only.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A compact vapor chamber, configured to thermally conduct heat of an electronic heat-generating element and including:
a flat sealed casing;
a wick structure arranged on inner walls of the flat sealed casing;
a working fluid filled inside the flat sealed casing; and
an evaporating section formed on a portion of the vapor chamber, an outer surface of the flat sealed casing on the evaporating section having a recess for covering the electronic heat-generating element, the recess being brought into thermal contact with a top surface of the electronic heat-generating element.

2. The compact vapor chamber according to claim 1, further including a supporting structure for supporting the wick structure to abut the inner walls of the flat sealed casing, the thickness of a portion of the supporting structure corresponding to the recess being smaller than that of the rest of the supporting structure.

3. The compact vapor chamber according to claim 2, further including a condensing section located away from the evaporating section and an adiabatic section extending between the evaporating section and the condensing section.

4. The compact vapor chamber according to claim 3, wherein the adiabatic section is formed into a straight line.

5. The compact vapor chamber according to claim 3, wherein the adiabatic section has at least one bending point to make the evaporating section not collinear with the condensing section.

6. The compact vapor chamber according to claim 3, wherein the number of the recess is plural.

7. The compact vapor chamber according to claim 3, wherein the recess is brought into thermal contact with the top surface and peripheral surfaces of the electronic heat-generating element.

8. A heat-dissipating module having a compact vapor chamber, configured to dissipate heat of an electronic heat-generating element and including:
a compact vapor chamber comprising:
a flat sealed casing;
a wick structure arranged on inner walls of the flat sealed casing;
a working fluid filled inside the flat sealed casing; and
an evaporating section formed on a portion of the vapor chamber, an outer surface of the flat sealed casing on the evaporating section having a recess for covering the electronic heat-generating element, the recess being brought into thermal contact with a top surface of the electronic heat-generating element; and
a heat-dissipating fin assembly connected to the other portion of the flat sealed casing away from the evaporating section.

9. The heat-dissipating module having a compact vapor chamber according to claim 8, wherein the compact vapor chamber further includes a condensing section located away from the evaporating section and an adiabatic section extending between the evaporating section and the condensing section.

10. The heat-dissipating module having a compact vapor chamber according to claim 9, wherein the recess is brought into thermal contact with the top surface and peripheral surfaces of the electronic heat-generating element.
